(19) United States
(12) Patent Application Publication
(10) Pub. No.: US 2004/0159286 A1
(43) Pub. Date: Aug. 19, 2004

(54) Plasma treatment device

(76) Inventors: Makoto Aoki, Shiroyama-machi, Tsukui-gun (JP); Hiraku Yoshitaka, Shiroyama-machi, Tsukui-gun (JP); Yoshihiro Kato, Shiroyama-machi, Tsukui-gun (JP); Shigeo Ashigaki, Shiroyama-machi, Tsukui-gun (JP); Syoichi Abe, Shiroyama-machi, Tsukui-gun (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/471,589

(22) PCT Filed: Mar. 13, 2002
(86) PCT No.: PCT/JP02/02350

(30) Foreign Application Priority Data
Mar. 13, 2001 (JP) 2001-70422

(51) Int. Cl. C23C 16/00

(52) U.S. Cl. 118/723 E; 118/722

(57) ABSTRACT

In a parallel plate type plasma processing apparatus (1), a baffle plate (28) is fitted between a ceiling (2b) and side wall (2a) of a chamber (2). The baffle plate (28) confines plasma into the upper portion of the chamber (2), and at the same time, constitutes a return route of a return current to a high frequency power source (27). A return current flowing through the baffle plate (28) returns to the high frequency power source (27) via the ceiling (2b) of the chamber (2).

### TECHNICAL FIELD

The present invention relates to a plasma processing apparatus which applies plasma processes such as a film forming process, an etching process, etc. to a process target such as a semiconductor wafers, etc.

### BACKGROUND ART

A plasma processing apparatus for applying surface treatment to a substrate by using plasma is used in the manufacturing process of a semiconductor device, a liquid crystal display device, etc. As plasma processing apparatuses, there are a plasma etching apparatus for applying an etching process to a substrate, a plasma CVD apparatus for applying a chemical vapor deposition (CVD) process to a substrate, etc. A parallel plate type plasma processing apparatus, among plasma processing apparatuses, is widely used, because it is excellent in process evenness, and its structure is relatively simple.

A parallel plate type plasma processing apparatus has two plate electrodes which face each other in parallel one above the other. A substrate, which is the process target, is placed on the electrode (lower electrode) under the other. A high frequency power source is connected to the electrode (upper electrode) above the other. By applying a high frequency voltage to the upper electrode, a high frequency electric field is formed in the space (a plasma generation space) between the upper and lower electrodes. A process gas such as an etching gas, etc. is supplied between the two electrodes, and is turned into plasma by the high frequency electric field. A predetermined process is applied to the surface of the substrate by active species in the plasma of the process gas.

In the plasma processing apparatus having the above-described structure, the process gas is supplied all the time during the process, and the generated plasma flows out from the plasma generation space. If the plasma flows out from the plasma generation space fast, the time during which the generated plasma is exposed to the substrate is short and the utilization efficiency of the plasma is decreased. Therefore, in order to prevent such an outflow of the plasma, a so-called baffle plate for confining the plasma in the plasma generation space is used.

A baffle plate is provided so as to block the flow passage of the gas flowing out from the plasma generation space. Fine holes having a shape of a slit, etc. are opened in the baffle plate. The fine holes allow a gas to pass therethrough, but hinder plasma from passing therethrough. In this way, generated plasma is confined in the plasma generation space by the baffle plate.

The baffle plate is made of a conductor. The baffle plate not only confines plasma as described above, but also functions as a flow passage of a high frequency electric current. That is, part of an electric current flowing from the high frequency power source flows through the upper electrode, the plasma, the baffle plate, and the chamber which is grounded, in this order, and returns to the high frequency power source.

However, the baffle plate is usually provided on the side wall of the chamber under the lower electrode. The return route in this case, which runs through the side wall of the chamber, is long, and has many interfaces (coupled surfaces) such as coupled portions between members included in the chamber. If there are many interfaces along the return route, the loss of the high frequency electricity due to the skin effect is large. That is, the conventional plasma processing apparatus, in which the baffle plate is provided on the side wall of the chamber, has a problem that the utilization efficiency of the high frequency electricity is low.

### DISCLOSURE OF INVENTION

To solve the above problem, an object of the present invention is to provide a plasma processing apparatus having a good high frequency electricity characteristic.

Another object of the present invention is to provide a plasma processing apparatus capable of reducing the loss of high frequency electricity.

To achieve the above objects, a plasma processing apparatus according to a first aspect of the present invention comprises:

a chamber (2) which is constituted by a plurality of conductive members (2a, 2b) which are electrically connected to each other;

a stage (7) which is provided inside the chamber (2), and on which a process target is placed;

an electrode (18) which is provided to one (2b), of the plurality of conductive members so as to be opposed to the stage (7), and which is connected to one end of a high frequency power source (27); and

a baffle plate (28) which is made of a conductive material, which is supported by the conductive member (2b) to which the electrode (18) is provided in a manner that the baffle plate (28) surrounds an outer circumference of the stage (7), and which confines plasma generated by applying a high frequency, voltage to the electrode (18) near the process target.

In the above-described structure, the baffle plate (28) may be provided so as to be sandwiched between the conductive member (2b) supporting the electrode (18) and the other conductive member (2a) adjoining the conductive member (2b).

In the above-described structure, the conductive member (2b) to which the electrode (18) is provided may be connected to the other end of the high frequency power source (27), and the baffle plate (28) may be supported by the conductive member (2b) by contacting the conductive member (2b).

To achieve the above objects, a plasma processing apparatus according to a second aspect of the present invention comprises:

a chamber (2) which is constituted by a plurality of conductive members (2a, 2b) which are electrically connected to each other;

a stage (7) which is provided inside the chamber (2), and on which a process target is placed;

an electrode (18) which is provided to one (2b) of the plurality of conductive members so as to be opposed to the stage (7), and which is connected to one end of a high frequency power source (27); and

a baffle plate (28) which is made of a conductive material, which is supported by the conductive member (2b) to which the electrode (18) is provided in a way that the baffle plate (28) surrounds an outer circumference of the stage (7), and which confines plasma generated by applying a high frequency voltage to the electrode (18) near the process target,

wherein the conductive member (2b) to which the electrode (18) is provided is connected to the other end of the high frequency power source (27), and the baffle plate (28) is supported by the conductive member (2b) by contacting the conductive member. (2b).

In the above-described structure, the baffle plate (28) may be constituted by a bottomed cylindrical member in whose center an opening (28b) through which the stage (7) penetrates is provided.

In the above-described structure, the bottomed cylindrical member may have an approximately L-shaped corner cross sectional shape, and an internal circumference of the opening (28b) may be arranged near a circumference of the process target.

In the above-described structure, the bottomed cylindrical member may have an approximately J-shaped corner portion cross sectional shape, and a bottom of the J-shaped corner portion may be arranged so as to be more separated than the process target from the electrode (18).

In the above-described structure, the baffle plate (28) may be constituted by a cylindrical member in which slits (28a) which extend in a direction approximately perpendicular to a principal surface of the process target are formed.

In the above-described structure, the stage (7) may comprise a step portion (31) near the slits (28a).

The plasma processing apparatus may further comprise an insulation member (30) which is provided so as to separate the baffle plate (28) and the stage (7) from each other.

### BRIEF DESCRIPTION OF DRAWINGS

FIG. 1 is a diagram showing a structure of a plasma processing apparatus according to a first embodiment of the present invention;

FIG. 2A shows a plan view of a baffle plate according to the first embodiment of the present invention, and FIG. 2B shows its cross sectional structure;

FIG. 3 is a diagram showing a state where the baffle plate shown in FIGS. 2 is installed;

FIG. 4A shows a cross sectional structure of a baffle plate according to another embodiment of the present invention, and FIG. 4B shows a state where this is installed;

FIG. 5A shows a cross sectional structure of a baffle plate according to a second embodiment of the present invention, and FIG. 5B shows a state where this is installed; and

FIG. 6 shows a state where a baffle plate according to another embodiment of the present invention is installed.

### BEST MODE FOR CARRYING OUT THE INVENTION

A plasma processing apparatus according to the embodiments of the present invention will now be explained with reference to the drawings. In the embodiments, explanation will be made by employing a plasma CVD (Chemical Vapor Deposition) apparatus as an example.

(First Embodiment)

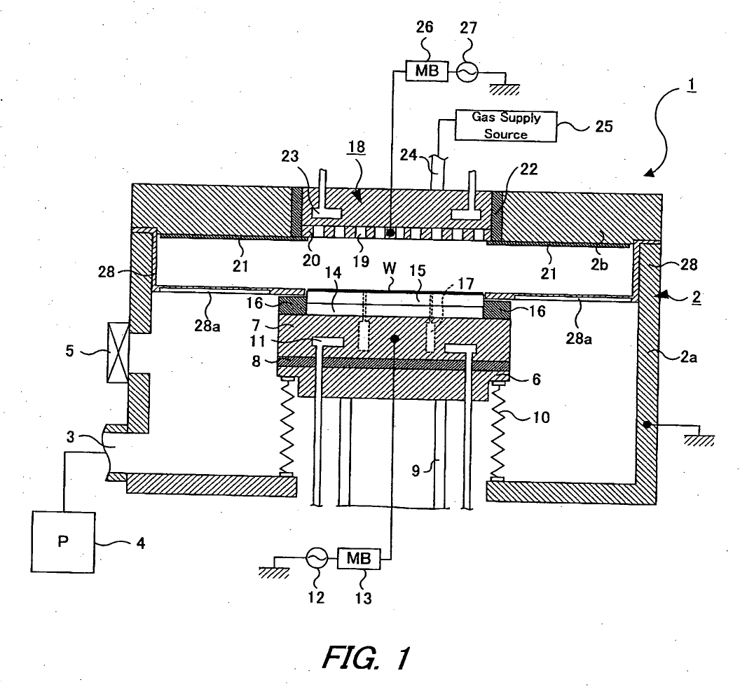

FIG. 1 shows a diagram of the structure of a plasma processing apparatus 1 according to a first embodiment.

The plasma processing apparatus 1 according to the present embodiment is constituted as a so-called parallel plate type plasma processing apparatus having parallel upper and lower electrodes facing each other, and has a function for forming a film, such as an SiOF film, etc. on the surface of a semiconductor wafer (hereinafter, referred to as wafer W).

With reference to FIG. 1, the plasma processing apparatus 1 comprises a chamber 2. The chamber 2 is formed as a cylinder. A side wall 2a and ceiling 2b of the chamber 2 can be separated from each other, and are integrated with each other by a screw, etc. The chamber 2 is made of a conductor such as aluminum, etc. which has been subjected to the almite process (anodic oxidation process). The chamber 2 is grounded.

An exhaust port 3 is provided at the bottom portion of the chamber 2. An exhaust device 4 having a vacuum pump such as a turbo molecular pump is connected to the exhaust port 3. The exhaust device 4 vacuums the inside of the chamber 2 to a predetermined depressurized atmosphere, for example, to a predetermined pressure equal to or lower than 0.01 Pa. A gate valve 5 is provided on the side wall 2a of the chamber 2. While the gate valve 5 is opened, a waver W is transported in and out between the chamber 2 and an adjoining load lock chamber (not shown).

A suceptor support 6 having an approximately cylindrical shape is provided at the bottom of the chamber 2. A suceptor 7 is provided on the suceptor support 6. The suceptor 7 serves as a lower electrode, as will be described later. The suceptor support 6 and the suceptor 7 are insulated from each other by an insulation member 8 such as ceramic. The suceptor support 6 is connected via a shaft 9 to an elevation mechanism (not shown) provided under the chamber 2, so as to be elevated and dropped.

The portions beneath the suceptor support 6 are covered with bellows 10 made of stainless steel, nickel, etc. The bellows 10 is separated into a vacuumed part in the chamber 2 and a part exposed in the air. The bellows 10 has its upper end and lower end screwed onto the lower surface of the suceptor support 6 and the bottom of the chamber 2, respectively.

A lower refrigerant flow passage 11 is provided inside the suceptor 7. A refrigerant circulates through the lower refrigerant flow passage 11. By the refrigerant circulating through the lower refrigerant flow passage 11, the suceptor 7 is controlled at a desired temperature.

The suceptor 7 is made of a conductor such as aluminum, etc. A first high frequency power source 12 is connected to the suceptor 7 via a first matching device 13. The first high frequency power source 12 applies a high frequency voltage having a frequency in the range of 0.1 to 13 MHz to the suceptor 7. The suceptor 7 having such a structure functions as a lower electrode.

A heater layer 14 is provided on the suceptor 7. The heater layer 14 is made of a plate-like insulation material such as ceramic, etc. The heating layer 14 has a resistor (not shown) embedded thereinside, so as to have a heating ability by applying a voltage to the resistor. The wafer W is heated to a predetermined process temperature by the heater layer 14.

A plate-like electrostatic chuck 15 is provided on the heater layer 14. The electrostatic chuck 15 constitutes a placement surface on which the wafer W is placed. The electrostatic chuck 15 has a structure in which an unillustrated electrode is covered with a dielectric material. With application of a direct current voltage to the electrode, the wafer W on the electrostatic chuck 15 is attracted and held by static electricity.

A ring-like focus ring 16 is provided around the suceptor 7, so as to surround the electrostatic chuck 15 and the heater layer 14. The focus ring 16 is made of a ceramic insulation material such as aluminum nitride, etc. The focus ring 16 gathers plasma into the inside thereof, and thereby increases the efficiency of supplying plasma active species onto the surface of the wafer W.

The top of the focus ring 16 is structured so as to be lower than the placement surface of the electrostatic chuck 15 on which the wafer W is placed. Due to this, the principal surface of a baffle plate, which will be described later, and the placement surface for the wafer W are arranged on almost the same plane.

The suceptor 7, the heater layer 14, and the electrostatic chuck 15, etc. comprise a lift pin 17 which penetrates therethrough so as to be able to move up and down. The lift pin 17 can project through the placement surface of the electrostatic chuck 15, and also can sink below the placement surface. The wafer W is handed over by the upward and downward movements of the lift pin 17.

Provided above the suceptor 7 is an upper electrode 18 which is opposed to this suceptor 7 in parallel. The surface of the upper electrode 18 that is opposed to the suceptor 7 comprises a disk-like electrode plate 20 made of aluminum, etc. and having multiple gas holes 19. The electrode plate 20 has its edge fixed by unillustrated screws.

The portions of the electrode plate 20 that are screwed are covered with an annular shield ring 21 made of an insulation material such as ceramic, etc. The shield ring 21 is formed such that the electrode plate 20 is exposed in approximately the center of the shield ring 21, and the ceiling 2b of the chamber 2 other than the electrode plate 20 is almost entirely covered by the shield ring 21. The shield ring 21 is fixed on the edge of the ceiling 2b of the chamber 2. The shield ring 21 forms a flat surface near the ceiling 2b of the chamber 2 including the screwed portions, and prevents occurrence of an abnormal discharge.

The upper electrode 18 is supported by the portion of the ceiling 2b of the chamber 2 via an insulation member 22. An upper refrigerant flow passage 23 is provided inside the upper electrode 18. A refrigerant is introduced into the upper refrigerant flow passage 23 to circulate therethrough, and thereby the upper electrode 18 is controlled at a desired temperature.

Further, the upper electrode 18 is provided with a gas supply portion 24, and the gas supply portion 24 is connected to a process gas supply source 25 outside the chamber 2. A process gas from the process gas supply source 25 is supplied via the gas supply portion 24 to a hollow portion (not shown) formed inside the upper electrode 18. The process gas supplied inside the upper electrode 18 is diffused in the hollow portion, and ejected from the gas holes 19 provided in the lower surface of the upper electrode 18 to the wafer W. Various gases, which have conventionally been used for forming an SiOF film, can be employed as the process gas. For example, SiF₄, SiH₄, O₂, NF₃, and NH₃, and Ar gas as a dilution gas can be used.

A second high frequency power source 27 is connected to the upper electrode 18 via a second matching device 26. The second high frequency power source 27 has a frequency in the range of 13 to 150 MHz, and produces highly dense plasma which is in a desirable dissociated state in the chamber 2, by applying such a high frequency.

A baffle plate 28 is sandwiched between the coupled portions of the ceiling 2b and side wall 2a of the chamber 2, so as to be fitted therebetween. The baffle plate 28 is made of a conductor such as aluminum, etc. which has been subjected to the almite process. The baffle plate 28 comprises fine holes 28a having a minute width. The fine holes 28a allow a gas to pass therethrough, but hinder plasma from passing therethrough. Therefore, plasma of the process gas caused between the suceptor 7 and the upper electrode 18 is confined between the upper portion of the chamber 2 and the baffle plate 28 (near the wafer W).

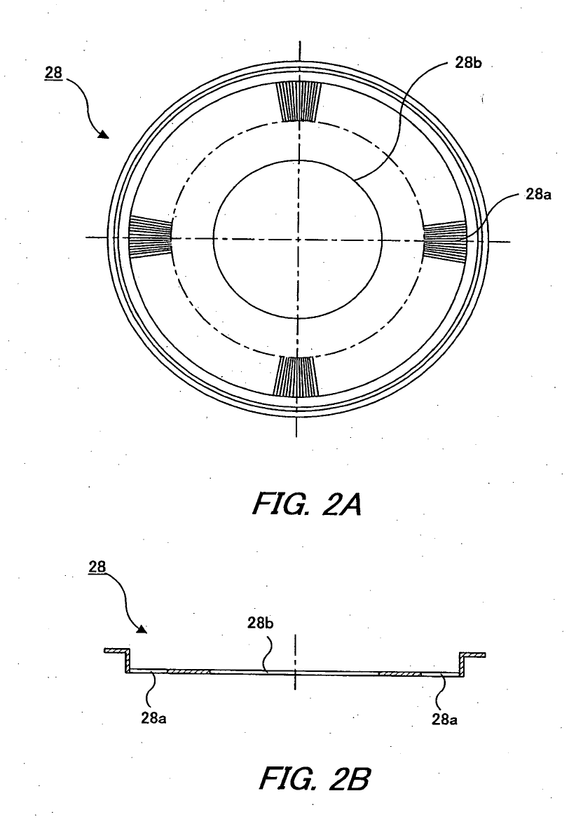

FIGS. 2A and 2B respectively show a plan view and a cross section of the baffle plate 28. As shown in FIG. 2A, an opening 28b is provided in the center of the baffle plate 28, and a plurality of fine holes 28a are opened radially around the opening 28b. The fine holes 28a are fine holes having a long and narrow shape, which are bored in the principal surface of the baffle plate 28 in the direction perpendicular to the principal surface. The width of the fine holes 28a is set to approximately 0.8 mm to 1 mm, so that plasma is hindered from passing while a gas is let through.

Further, as shown in FIG. 2B, the baffle plate 28 is constituted by a cylindrical member which has a bottom, and whose corner has an L-shaped cross section. The opening 28b has almost the same area as the area of the wafer W. At the time of processing, the internal circumference of the opening 28b is arranged at a position close to the outer circumference of the wafer W which is placed on the suceptor 7. The surface of the baffle plate 28 in which the fine holes 28a are formed is arranged so as to be almost the same plane as the placement surface for the wafer W. Therefore, the surface of the wafer W that is to be processed is exposed in the opening 28b of the baffle plate 28, so as to be exposed to plasma which is generated between the suceptor 7 and the upper electrode 18. At this time, the space in which the plasma is generated is defined by the ceiling 2b of the chamber 2, the electrode plate 20, the wafer W, and the baffle plate 28.

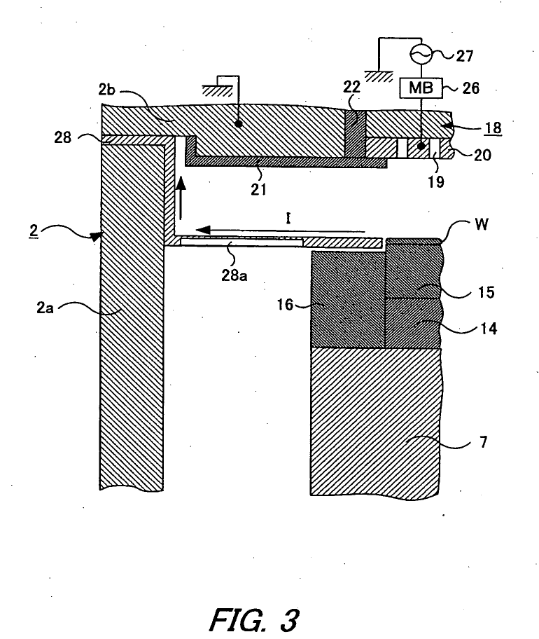

FIG. 3 shows a state where the baffle plate 28 is installed inside the plasma processing apparatus 1. As shown in FIG. 3, the baffle plate 28 is sandwiched between the side wall 2a and ceiling 2b of the chamber 2, and fixed by screws (not shown). As a result, the side wall 2a and ceiling 2b of the chamber 2, and the baffle plate 28 are electrically connected to one another.

The side surface of the L-shaped corner of the baffle plate 28 is arranged along the side wall 2a of the chamber 2, and the side wall 2a of the chamber 2 is therefore protected from plasma On the other hand, the bottom (the surface in which the fine holes 28a are formed) of the L-shaped corner is arranged so as to be almost the same plane as the wafer W which is placed on the electrostatic chuck 15. Further, the bottom is separated from the electrostatic chuck 15 and the focus ring 16 by approximately 1 to 3 mm. However, the baffle plate 28 may contact the focus ring 16.

The baffle plate 28 is made of a conductor, and part of a return current of a high frequency electric current which is generated by high frequency electricity applied to the upper electrode 18 flows through the surface of the baffle plate 28 due to the skin effect The route of the return current to the second high frequency power source 27 via the baffle plate 28 is shown by an arrow I in FIG. 3. As shown by the arrow I, the return current flows through the surface of the baffle plate 28, and flows to the coupled portions of the side wall 2a and ceiling 2b of the chamber 2. Since the chamber 2 is at a ground potential, the return current returns from the ground to the second high frequency power source 27.

Since the route of the return current through the baffle plate 28 as described above, is directly connected to the ceiling 2b of the chamber 2, which is the same as the upper electrode 18, that is, directly connected near the second high frequency power source 27, the route is substantially shorter than in a case where a baffle plate is provided on the side wall 2a of the chamber 2 as conventional.

Further, in a case where the baffle plate 28 is provided on the side wall 2a of the chamber 2, the baffle plate 28 is provided so as to be embedded in the side wall 2a of the chamber 2 to divide the side wall 2a into upper and lower parts, and thereby an interface is formed where the baffle plate 28 is provided. Accordingly, interfaces in the return route increase. Since the fewer the interfaces existing in the route, the less the loss of the high frequency electricity due to the skin effect is, the structure wherein the baffle plate 28 is provided between the ceiling 2b and side wall 2a of the chamber 2 enables plasma processing which is high in the utilization efficiency of the high frequency electricity. Further, the side wall 2a of the chamber 2 can be protected form plasma by the baffle plate 28.

An operation of the plasma processing apparatus 1 having the above-described structure when forming an SiOF film on a wafer W, will be explained with reference to FIG. 1.

First, the suceptor support 6 is moved by the unillustrated elevation mechanism to a position at which the wafer W can be transported. Then, after the gate valve 5 is opened, the wafer W is transported into the chamber 2 by an unillustrated transportation arm. The wafer W is placed on the lift pin 17, which is in a state of projecting through the suceptor 7. Next, the wafer W is placed on the electrostatic chuck 15 in accordance with the drop of the lift pin 17, and after this, is electrostatically attracted. Then, the gate valve 5 is closed, and the exhaust device 4 exhausts the inside of the chamber 2 of the air to a predetermined vacuum pressure. After this, the suceptor support 6 is elevated to the processing position by the unillustrated elevation mechanism.

In this state a refrigerant is circulated through the lower refrigerant flow passage 11 to control the suceptor 7 at a predetermined temperature, for example, 50° C., and the chamber 2 is exhausted by the exhaust device 4 via the exhaust port 3 to be a highly vacuumed state, for example, 0.01 Pa.

After this, a process gas, for example, SiF₄, SiH₄, O₂, NF₃, and NH₃ gases, and Ar gas as a dilution gas, is supplied while being controlled at a predetermined flow rate, from the process gas supply source 25 into the chamber 2. The process gas and a carrier gas supplied to the upper electrode 18 are ejected toward the wafer W uniformly from the gas holes 19 of the electrode plate 20.

After this, high frequency electricity of, for example, 50 to 150 MHz is applied to the upper electrode 18 by the second high frequency power source 27. Due to this, a high frequency electric field is caused between the upper electrode 18 and the suceptor 7 as a lower electrode, and the process gas supplied from the upper electrode 18 is turned into plasma. On the other hand, high frequency electricity of, for example 1 to 4 MHz is applied by the first high frequency power source 12 to the suceptor 7 as a lower electrode. As a result, active species in the plasma are drawn to the side of the suceptor 7, and the density of plasma near the surface of the wafer W is heightened. By the application of the high frequency electricity to the upper and lower electrode 7 and 18, plasma of the process gas is generated, and the chemical reaction of the generated plasma on the surface of the wafer W forms an SiOF film on the surface of the wafer W.

As explained above, in the plasma processing apparatus 1 according to the first embodiment, the baffle plate 28 for confining plasma near the wafer W is provided between the ceiling 2b and side wall 2a of the chamber 2. Because of this, the return current to the second high frequency power source 27 that flows through the baffle plate 28 can return to the second high frequency power source 27 by taking a route that is short and has a small number of interfaces. Accordingly, plasma processing which achieves a decrease in the loss of high frequency electricity due to the skin effect and is therefore high in the utilization efficiency of the high frequency electricity, is available.

According to the above-described first embodiment, the bottom of the baffle plate 28 constitutes almost the same plate as the wafer W which is placed on the electrostatic chuck 15. However, the present invention is not limited to this, but the lower surface of the baffle plate 28 may be positioned anywhere as long as it forms a structure by which plasma is effectively confined near the wafer W.

According to the above-described first embodiment, the baffle plate 28 has corners whose cross section is L-shaped as shown in FIG. 2A. However, the shape of the baffle plate 28 is not limited to this, but the baffle plate 28 may be fixed on the ceiling 2b of the chamber 2 or may be structured in any way as long as a route of the return current of the high frequency electric current will be short.

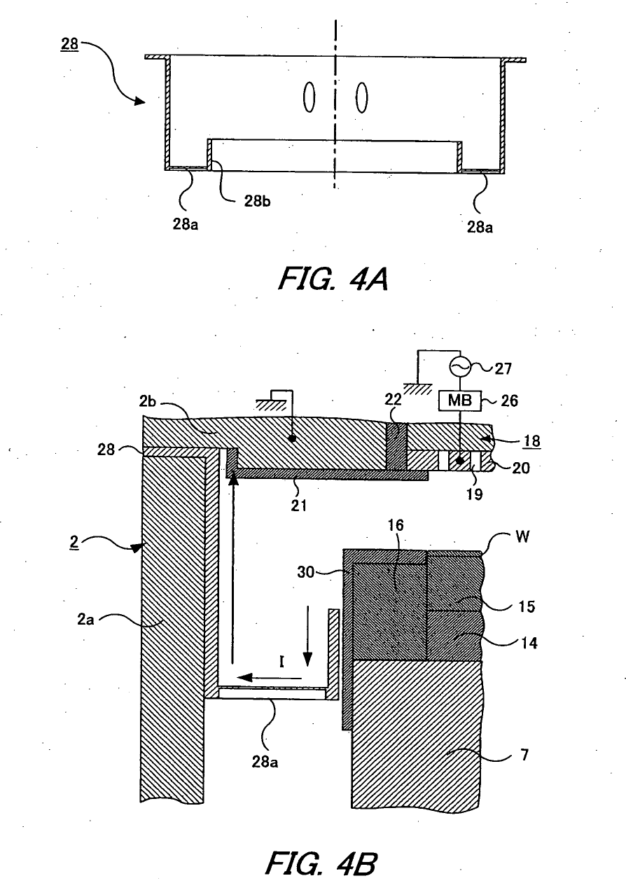

For example, a baffle plate 28 shown in FIG. 4A, whose corner portion has a J-shaped cross section is employable. This baffle plate 28 is a bottomed cylindrical member which comprises fine holes 28a in the corner portion and an opening 28b in the center likewise the L-shaped baffle plate 28 described above. The baffle plate 28b is, for example, screwed between the ceiling 2b and side wall 2a of the chamber 2.

FIG. 4B shows a diagram in a case where the baffle plate 28 shown in FIG. 4A is installed. In the structure shown in FIG. 4B, the portion above the suceptor 7 is covered with a thin plate-like insulation member 30 made of ceramic, etc. The insulation member 30 is formed to be a cylindrical shape having a bottom. An opening having almost the same diameter as that of the wafer W is formed in the bottom of the insulation member 30, and the internal diameter of the cylindrical portion is almost the same as the outer diameter of the suceptor 7. The insulation member 30 is provided to cover the portion above the suceptor 7 in such a way that the wafer W is exposed in the opening.

The opening 28b of the baffle plate 28 has a diameter larger than the outer diameter of the insulation member 30, and an internal side wall 2a of the J-shaped structure of the corner portion is arranged to be separated from the outer circumference of the suceptor 7 by approximately 1 mm to 3 mm. The fine holes 28a are formed in the bottom of the J-shaped portion that is enclosed by two side walls 2a. The surface in which the fine holes 28a are formed is positioned at the air exhaustion side lower than the position at which the wafer W is placed.

By forming the cross section of the corner portion to be the J shape, it is possible to expand the plasma generation space and to obtain a desired plasma density or a desired reaction pressure.

Further, since the J-shaped baffle plate 28 can also be provided between the ceiling 2b and side wall 2a of the chamber 2, the return route of the high frequency electric current becomes short and has a small number of interfaces. Accordingly, the same effect as the case of the L-shaped baffle plate 28, such as a high utilization efficiency of the high frequency electricity, etc., can be obtained. Further, the insulation member 30 prevents a short circuit between the baffle plate 28 and the suceptor 7.

Further, according to the above-described first embodiment, the process target wafer W is not rotated when it is processed. In this case, the baffle plate 28 may be provided to the suceptor 7 or the support of the suceptor 7.

According to the above-described first embodiment, the fine holes 28a formed in the baffle plate 28 have a long and narrow shape (slit shape). However, the shape of the fine holes 28a is not limited to this, but any shapes may be employed as long as they allow a gas to pass therethrough while confining plasma. For example, the fine holes 28a may have a circle shape, a honeycomb shape, etc.

(Second Embodiment)

A second embodiment of the present invention will now be explained with reference to the drawings. Components that are identical with those shown in FIG. 4B will be denoted by the same reference numerals.

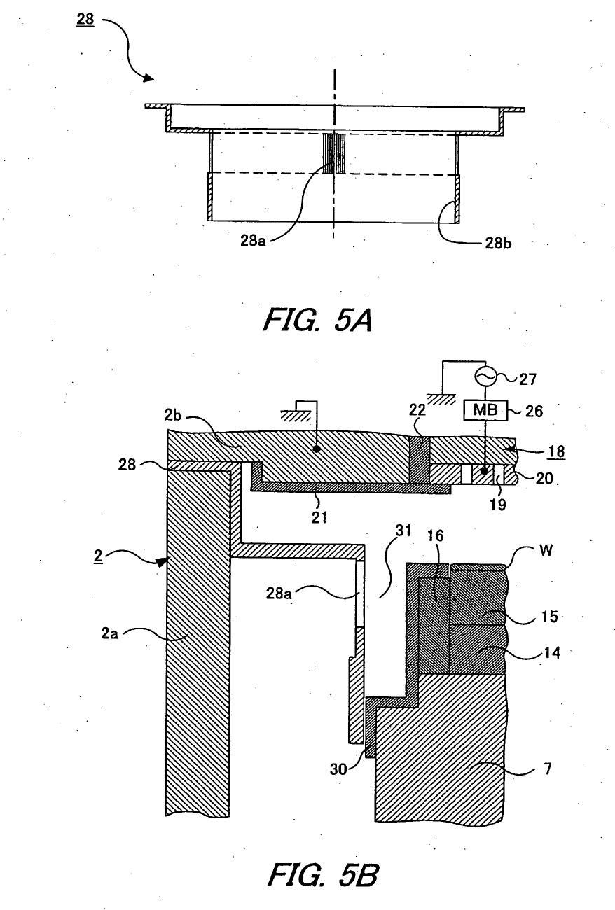

FIG. 5A shows the structure of a baffle plate 28 according to the second embodiment. As shown in FIG. 5A, the baffle plate 28 is constituted by a cylindrical member made of a semiconductor such as aluminum, etc. The baffle plate 28 has a cylindrical portion 28b comprising fine holes 28a.

The fine holes 28a have a long and narrow shape which is bored in the direction perpendicular to the principal surface of the baffle plate 28. The width of the fine holes 28a is approximately 0.8 mm to 1 mm, so that plasma is hindered from passing, while a gas is allowed to pass through. The fine holes 28a are formed in the side wall of the cylindrical portion 28b in, for example, approximately 5 cm long in a direction along which the cylinder of the cylindrical portion 28b is formed (the direction perpendicular to the principal surface of the suceptor 7, as will be described later).

FIG. 5B shows an example where the baffle plate 28 is installed in the plasma processing apparatus 1. In the structure shown in FIG. 5B, the portion above the suceptor 7 is covered by a bottomed cylindrical insulation member 30, likewise the structure shown in FIG. 4B. The insulation member 30 has a function for preventing a short circuit between the baffle plate 28 and the suceptor 7, etc.

The baffle plate 28 is installed to be fitted between the coupled portions of the side wall 2a and ceiling 2b of the chamber 2. The cylindrical baffle plate 28 is likewise arranged so as to surround the outer circumference of the insulation material 30. The cylindrical portion 28b has a diameter larger than the outer diameter of the insulation material 30 by approximately 1 mm to 3 mm.

The return current of high frequency electricity flows through the baffle plate 28 to the ground from the coupled portions of the ceiling 2b and side wall 2a of the chamber 2. In this way, the return current returns to the second high frequency power source 27 via a route which is substantially short and has a small number of interfaces.

A step portion 31 having a smaller outer diameter than that of the lower portion of the suceptor 7 is provided at a place above the suceptor 7 near the area where the fine holes 28 a are formed. The step portion 31 is provided in order for the fine holes 28 not to be blocked by the suceptor 7, etc.

The fine holes 28a may be formed in any length in the direction in which they extends on the cylindrical portion 28b (in the direction perpendicular to the principal surface of the suceptor 7). Accordingly, by appropriately adjusting the area in which the step portion 31 is formed, it is possible to desirably sufficiently secure passability (conductance) of a gas passing through the fine holes 28a.

As described above, in the plasma processing apparatus 1 according to the second embodiment, the return current to the second high frequency power source 27 that flow through the baffle plate 28 can return to the second high frequency power source 27 by taking a route that is substantially short and has a small number of interfaces. Therefore, plasma processing which achieves a decrease in the loss of high frequency electricity due to the skin effect and is therefore high in the utilization efficiency of the high frequency electricity, is available.

Further, the length of the fine holes 28a of the baffle plate 28 can be lengthened desirably along the cylindrical portion 28b. Accordingly, the length of the slits is not limited to within the distance between the side wall 2a of the chamber 2 and the insulation material 30 (or the suceptor 7), such as in a case where the slits are provided in the direction horizontal to the principal surface of the suceptor 7. By providing this structure wherein the slits are formed in the perpendicular direction and adjusting the slit length adequately, it is possible to control the plasma generation space at a desired pressure.

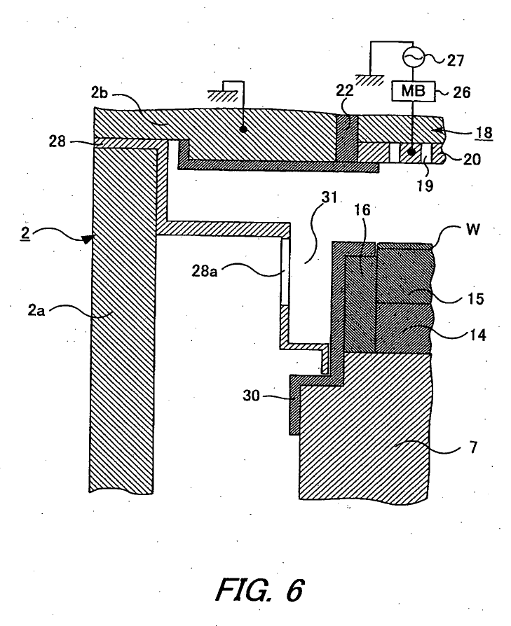

In the second embodiment described above, the shape of the baffle plate 28 may be replaced with other shapes, for example, the shape shown in FIG. 6. As shown in FIG. 6, the baffle plate 28 is shaped such that the portion under the fine holes 28a is bent in the step portion 31. According to this structure, an effect that the strength of the fine holes 28a of the baffle plate 28 and its neighborhood are enhanced can be obtained.

The area where the step portion 31 is formed is not limited to the above-described example, but may be formed in any manner as long as a space that gives a desired conductance near the wafer W can be formed.

According to the first and second embodiments described above, the baffle plate 28 is structured so as to be fitted between the side wall 2a and ceiling 2b of the chamber. However, the baffle plate 28 may be supported in any manner as long as the baffle plate 28 is so structured as to directly contact the ceiling 2b of the chamber 2.

According to the first and second embodiments described above, the slit-like fine holes or slits are bored in the direction perpendicular to the principal surface of the baffle plate. However, the formation of slits is not limited to this, but any formation that restricts passage of plasma and gives a desired conductance, such as a formation obtained by boring slits diagonally to the principal surface, and a formation obtained by boring slits in a tapered shape, is employable.

According to the first and second embodiments described above, the insulation member 30 is provided at the portion above the suceptor 7. However, the insulation member 30 may not be provided.

According to the first and second embodiments described above, the baffle plate 28 is structured so as to directly contact the side wall 2a of the chamber 2. However, a structure in which an insulation member such as ceramic, etc. is provided between the side surface of the baffle plate 28 and the side wall 2a of the chamber 2 is employable. By restricting electrical contact between the side wall 2a of the chamber 2 and the baffle plate 28 in this way, it is possible to further decrease the loss of high frequency electricity.

According to the first and second embodiments described above, the baffle plate 28 is made of aluminum which has been subjected to the almite process. However, the material of the baffle plate 28 is not limited to this, but any conductive material that is high in resistance against plasma, such as alumina, yttria, etc., may be used. Due to this, a high plasma resistance of the baffle plate 28 can be obtained, and a high maintenanceability of the entire plasma processing apparatus 1 can be obtained.

In the above-described embodiments, a parallel plate type plasma processing apparatus which applies a process for forming an SiOF film to a semiconductor wafer has been explained. However, the process target is not limited to a semiconductor wafer, but the process may be applied to a liquid crystal display device, etc. Further, the film to be formed may be any film such as SiO₂, SiN, SiC, SiCOH, CF films, etc. Further, the gas to be used for film forming is not limited to the above-described example.

Further, plasma processing to be applied to a process target is not limited to a film forming process, but the present invention can be applied to an etching process, etc. Furthermore, the plasma processing apparatus is not limited to a parallel plate type, but any types including a magnetron type, an ECR type, an ICP type, etc. may be used.

### Industrial Applicability

The present invention can suitably be applied to a plasma processing apparatus which applies plasma processing such as plasma etching, plasma CVD, etc. to a process target by using plasma.

The present invention is based on Japanese Patent Application No. 2001-70422 filed on Mar. 13, 2001, and including its specification, claims, drawings, and abstract. The disclosure of the above application is incorporated herein by reference in its entirety.

1. A plasma processing apparatus comprising:
a chamber (2) which is constituted by a plurality of conductive members (2a, 2b) which are electrically connected to each other;
a stage (7) which is provided inside said chamber (2), and on which a process target is placed;
an electrode (18) which is provided to one (2b) of said plurality of conductive members so as to be opposed to said stage (7), and which is connected to one end of a high frequency power source (27); and
a baffle plate (28) which is made of a conductive material, which is supported by said conductive member (2b) to which said electrode (18) is provided in a manner that said baffle plate (28) surrounds an outer circumference of said stage (7), and which confines plasma generated by applying a high frequency voltage to said electrode (18) near said process target.

2. The plasma processing apparatus according to claim 1,
wherein said baffle plate (28) is provided so as to be sandwiched between said conductive member (2b) supporting said electrode (18) and the other conductive member (2a) adjoining said conductive member (2b).

3. The plasma processing apparatus according to claim 1,
wherein said conductive member (2b) to which said electrode (18) is provided is connected to the other end of said high frequency power source (27), and said baffle plate (28) is supported by said conductive member (2b) by contacting said conductive member 2b).

4. A plasma processing apparatus comprising:
a chamber (2) which is constituted by a plurality of conductive members (2a, 2b) which are electrically connected to each other;
a stage (7) which is provided inside said chamber (2), and on which a process target is placed;
an electrode (18) which is provided to one (2b) of said plurality of conductive members so as to be opposed to said stage (7), and which is connected to one end of a high frequency power source (27); and
a baffle plate (28) which is made of a conductive material, which is supported by said conductive member (2b) to which said electrode (18) is provided in a way that said baffle plate (28) surrounds an outer circumference of said stage (7), and which confines plasma generated by applying a high frequency voltage to said electrode (18) near said process target,
wherein said conductive member (2b) to which said electrode (18) is provided is connected to the other end of said high frequency power source (27), and said baffle plate (28) is supported by said conductive member (2b) by contacting said conductive member (2b).

5. The plasma processing apparatus according to claim 4,
wherein said baffle plate (28) is constituted by a bottomed cylindrical member in whose center an opening (28b) through which said stage (7) penetrates is provided.

6. The plasma processing apparatus according to claim 5,
wherein said bottomed cylindrical member has an approximately L-shaped corner cross sectional shape, and an internal circumference of said opening (28b) is arranged near a circumference of said process target.

7. The plasma processing apparatus according to claim 5,
wherein said bottomed cylindrical member has an approximately J-shaped corner portion cross sectional shape, and a bottom of said J-shaped corner portion is arranged so as to be more separated than said process target from said electrode (18).

8. The plasma processing apparatus according to claim 4,
wherein said baffle plate (28) is constituted by a cylindrical member in which slits (28a) which extend in a direction approximately perpendicular to a principal surface of said process target are formed.

9. The plasma processing apparatus according to claim 8,
wherein said stage (7) comprises a step portion (31) near said slits (28a).

10. The plasma processing apparatus according to claim 4, further comprising an insulation member (30) which is provided so as to separate said baffle plate (28) and said stage (7) from each other.
